(19) United States
(12) Patent Application Publication
(10) Pub. No.: US 2013/0008509 A1
(43) Pub. Date: Jan. 10, 2013

(54) INVERTED POLYMER SOLAR CELL USING A DOUBLE INTERLAYER

(75) Inventors: JEGADESAN SUBBIAH, Gainesville, FL (US); FRANKY SO, Gainesville, FL (US); JOHN R. REYNOLDS, Dunwoody, GA (US)

(73) Assignee: UNIVERSITY OF FLORIDA RESEARCH FOUNDATION, INC., Gainesville, FL (US)

(21) Appl. No.: 13/533,547

(22) Filed: Jun. 26, 2012

Related U.S. Application Data
(60) Provisional application No. 61/505,618, filed on Jul. 8, 2011.

(51) Int. Cl. H01L 51/46; B82Y 99/00

(52) U.S. Cl. 136/263; 977/948

(57) ABSTRACT

A polymer based solar cell having an inverted geometry includes a transparent cathode and a double interlayer that has a hole extracting layer and a hole transport/electron blocking layer situated between an active layer, for example, a bulk heterojunction (BHJ) layer, and an anode. The inverted solar cells according to embodiments of the invention display significant efficiency improvements over polymer based solar cells that do not have the inverted geometry and lack the double interlayer.

### CROSS-REFERENCE TO RELATED APPLICATION

The present application claims the benefit of U.S. Provisional Application Serial No. 61/505,618, filed Jul. 8, 2011, which is hereby incorporated by reference herein in its entirety, including any figures, tables, or drawings.

### BACKGROUND OF INVENTION

Organic photovoltaic (OPV) cells are increasingly being investigated as an alternative to Si solar cells. OPV cells generally fall into three categories: dye-sensitized cells; polymer cells; and small-molecule cells. In particular, polymer cells have the potential to be low-cost, light-weight, mechanically flexible, and permit use of high throughput manufacturing techniques. Polymer solar cells include an active layer where a polymer, such as a regio-regular poly(3-hexylthiophene) (P3HT), is combined with a fullerene derivative, such as [6,6]-phenyl-C₆₁ butyric acid methyl ester (PCBM), to form a phase-separated bulk-heterojunction (BHJ) having a large interfacial area for exciton dissociation. The photo-excited polymer functions as an electron donor, to transporter holes to the cell's anode, and the fullerene derivative functions as an electron acceptor, to transport electrons to the cell's cathode.

It is commonly held that the magnitude of open-circuit voltage (V_{oc}) is primarily limited by the energy difference between the highest occupied molecular orbital (HOMO) of the BHJ donor material and the lowest unoccupied molecular orbital (LUMO) of the acceptor material. Although this difference defines the theoretical maximum V_{oc}, output is typically 300 to 500 mV below this maximum value in an actual device. Schottky barriers formed at the interfaces are believed to be a source of this deviation from optimal behavior. To reduce the Schottky barriers, it is desirable to understand and control interfacial dipoles, where modification can be carried out by carefully selecting materials to mediate the interface. In addition, the use of an effective electron-blocking layer (EBL)/hole-transporting layer (HTL) can prevent current leakage and enhance the device's output. Throughout the organic solar cell literature, the use of a transparent electrode as a hole collecting electrode is dominant. Often the transparent electrode is indium-tin-oxide (ITO) on a transparent substrate. Additionally, the ITO electrode is coated with a polymeric hole transporting layer (HTL), such as polyethylenedioxythiophene/polystyrenesulfonate (PEDOT/PSS). An alternative to PEDOT:PSS has been the deposition of a thin metal oxide layer, for example, a NiO or MoO₃ layer, on top of an indium-tin-oxide (ITO) anode, which has been demonstrated to improve hole transport from the active polymer layer to the anode.

The vertical phase morphology plays a crucial role in determining the power conversion efficiency. There are few examples in the literature where the transparent electrode, generally ITO, is modified to be the electron capturing electrode of the photovoltaic (PV) device. Devices where the ITO captures electrons are described as solar cells having an “inverted geometry”. The inverted device geometry has been shown to optimize vertical phase segregation in a donor polymer-PCBM system for efficient solar cell performance. The improved efficiency is believed to be the result of a concentration gradient of the fullerenes, where the concentration is higher at the bottom of the conjugated polymer:fullerene blend, and, therefore, having the electron capturing electrode on the bottom face of the active film is desired.

### BRIEF SUMMARY

Embodiments of the invention are directed to polymer solar cells that include a transparent cathode and a double interlayer comprising a hole extracting layer and a hole transport/electron blocking layer, where the double interlayer is situated between the cell's active layer and anode. The hole extracting layer can be a metal oxide, such as MoO₃, V₂O₅, NiO, or WO₃. The metal oxide can be in the form of nanoparticles. Alternately, the hole extracting layer can be an organic electron accepting transport material, for example, HAT(CN)₆, F₁₆-CuPc, F4TCNQ, PTCDA, fluoro-substituted PTCDA, cyano-substituted PTCDA, NTCDA, fluoro-substituted NTCDA, cyano-substituted NTCDA, or PTCBI. The hole transport/electron blocking layer can be, for example, MTDATA, TFB, poly-TPD, TPD, α-NPD, DHABS, DPABS, or an TFB analogue.

The polymer solar cell, according to an embodiment of the invention, has an inverted geometry with a transparent cathode, such as ITO. Alternately, the transparent cathode can be ITO/Ag/ITO, Al doped ZnO/metal, a thin metal layer, doped or undoped single walled carbon nanotubes (SWNTs), or patterned metal nanowires comprising gold, silver, or copper.

The polymer solar cell, according to an embodiment of the invention, has an anode that can be a metal or a metal alloy. The metal can be, but is not limited to, silver (Ag), calcium (Ca), aluminum (Al), magnesium (Mg), titanium (Ti), tungsten (W), or gold (Au).

According to an embodiment of the invention, the polymer solar cell can include a cathode interlayer situated between the active layer and the transparent cathode. The cathode interlayer can be, for example, ZnO, LiF, LiCoO₂, CsF, Cs₂CO₃, or TiO₂. Alternately, the cathode interlayer can be a polar or ionic polymer, for example, polyethylene oxide (PEO).

In an embodiment of the invention, the active layer of the polymer solar cell is a bulk heterojunction (BHJ) active layer, where an electron-donating material is combined with an electron-accepting material. The electron-donating material of the BHJ can be, for example, DTSBTD, P3HT, PFDTBT, PCPDTBT, PE-PPV, APFO-5, PBDTTT-C, PBDTTT-E, PCDTBT, AlPeCl, or CuPc. The electron-accepting material of the BHJ can be, for example, PC₇₀BM, PC₆₀BM, ZnO nanoparticles, N-alkyl or N-aryl perylenediimides, perylenediimide containing polymers, CNPPV, TiO₂ nanoparticles, or Cd/Pb-based nanoparticles.

### BRIEF DESCRIPTION OF DRAWINGS

FIG. 1 shows a schematic representation of an inverted PV device with a double anode interlayer, according to an embodiment of the invention.

FIG. 2 is a composite J-V plot of a conventional PV device and an inverted PV device with a double anode interlayer, according to an embodiment of the invention, where the active layer is a blend of poly[(4,4′-bis(2-ethylhexyl)dithienol[3,2-b:2′, 3′-d]silole)-2,6-diyl-alt-(2,1,3-benzothiadiazole)-4,7diyl (DTSBTD) and {6,6}-phenyl-C₇₁ butyric acid methyl ester (PC₇₀BM) upon irradiation with 1.5 solar illumination at 100 mW cm⁻².

FIG. 3 shows plots of external quantum efficiencies (EQEs) over the visible light spectrum for PV devices with DTSBTD:PC₇₀BM active layers in a conventional geometry and in an inverted geometry with an included double anode interlayer, according to an embodiment of the invention.

FIG. 4 is a composite J-V plot of a conventional PV device and an inverted PV device with a double anode interlayer, according to an embodiment of the invention, where the active layer is a blend of poly(3-hexylthiophene) (P3HT):PC₇₀BM upon irradiation with 1.5 solar illumination at 100 mW cm⁻².

FIG. 5 is an energy level diagram showing the relative energies of exemplary electrode materials, active layer materials, and MTDATA, according to embodiments of the invention.

### DETAILED DISCLOSURE

Embodiments of the invention are directed to inverted solar cells where, for example, thin layers of ZnO nanoparticles and MoO₃ were used as interlayers for the bottom cathode and the top anode, respectively, and where a second interlayer, a wide band-gap electron blocking hole transporting layer (HTL), is situated between the active layer and hole extraction interlayer, MoO₃, to further enhance the inverted solar cell's performance because of the double interlayer at the anode. The anode double layer comprises a semiconducting metal oxide layer for hole extracting and an organic hole transporting electron blocking material layer. In one embodiment or the invention, the HTL is a thin film of 4,4′,4″-tris[N-(3-methylphenyl)-N-phenylamino]triphenylamine (MTDATA). The inclusion of the HTL/MoO₃ anode double interlayer improves the hole extraction from the photoactive layer and improves hole transport to the anode. By using the double interlayer as a hole extraction/electron blocking layer at the top anode, an improvement of the short-circuit current and power conversion efficiency (PCE) of polymer photovoltaic (PV) cells results. In this double interlayer structure, the MoO₃ layer enhances the extraction of holes from the active layer, while the MTDATA layer transports holes to the anode while blocking electrons that would otherwise combine with holes at or near the anode. In one exemplary embodiment of the invention, significant enhancements in power conversion efficiencies are achieved for organic photovoltaic (OPV) cells with the double interlayer structures where a polythiophene and silole containing donor-acceptor polymer is within the active materials.

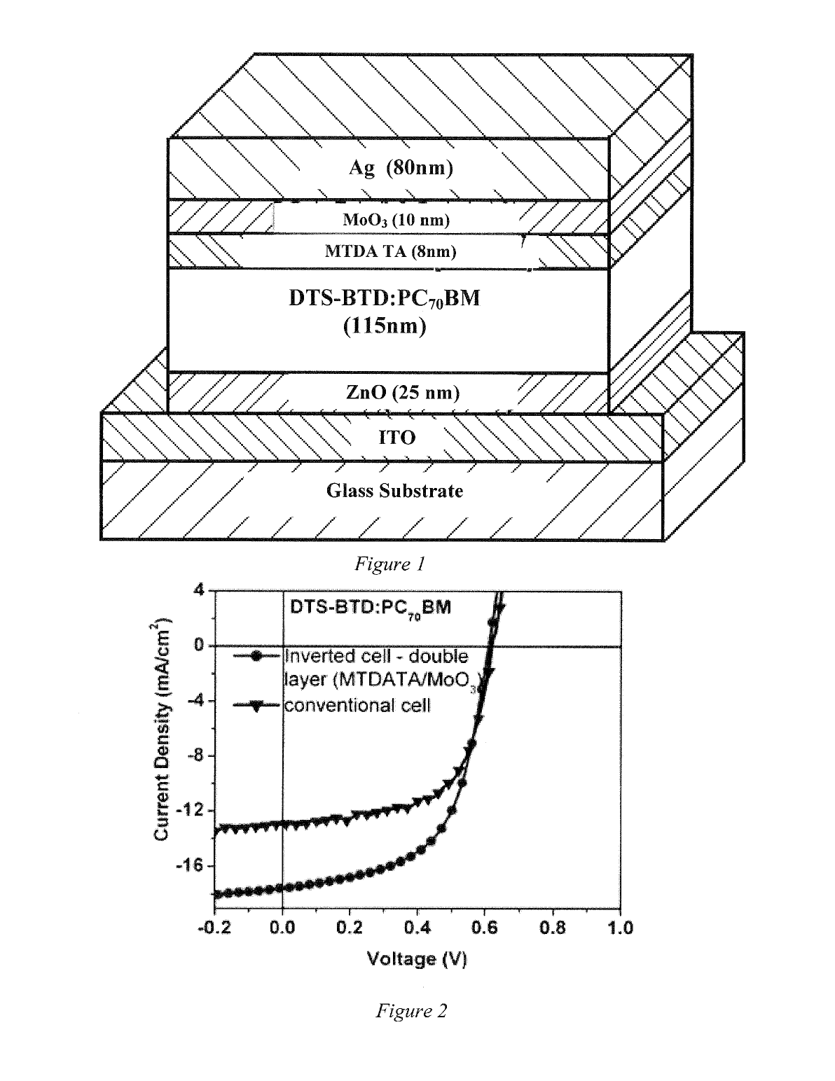

In an embodiment of the invention, a solar cell uses the double interlayer, for example, MoO₃ and MTDATA, with a bulk heterojunction (BHJ) conjugated polymer:fullerene active layer. In an exemplary embodiment, the BHJ comprises a blend of poly ((4,4′-bis(2-ethylhexyl)dithienol [3,2-b: 2′,3°-d]silole)-2,6-diyh-alt-(2,1,3-benzothiadiazole)-4,7-diyl) (DTSBTD) and {6,6}-phenyl-C71 butyric acid methyl ester (PC₇₀BM), as shown in the schematic diagram of FIG. 1. The inverted solar cell shown in FIG. 1, ITO/ZnO/DTSBTD: PC₇₀BM/MTDATA/MoO₃/Ag, employs a thin zinc oxide (ZnO) nanoparticle layer as a bottom cathode contact layer. For comparison, the inverted solar cell's performance is presented with that of a conventional photovoltaic device: ITO/MoO₃/(DTSBTD:PC₇₀BM)/LiF/Al. The current density-voltage (I-V) characteristics of the inverted and conventional PV devices are shown in FIG. 2. The conventional DTS-BTD:PC₇₀BM PV cell has a photocurrent efficiency (PCE) of 4.91%, a short-circuit current density (J_{sc}) of 12.78 mA/cm², an open-circuit voltage (V_{oc}) of 0.61 V, and a fill factor (FF) of 0.61. The term fill factor (FF), as used herein, refers to the ratio of the maximum power (Vₘₚ×Jₘₚ) divided by the short-circuit current density (J_{sc}) and open-circuit voltage (V_{oc}) displayed among the light current density-voltage (J-V) characteristics of solar cells. The term short circuit current density (J_{sc}), as used herein, is the maximum current through the load under short-circuit conditions. The term open circuit voltage (V_{oc}), as used herein, is the maximum voltage obtainable at the load under open-circuit conditions. The term power conversion efficiency (PCE), as used herein, is the ratio of the electrical power output to the light power input (Pᵢₙ), defined as PCE=V_{oc}J_{sc}FFPᵢₙ⁻¹, which is generally reported as a percentage. An inverted device with a MoO₃ interlayer between the photoactive layer and silver (Ag) anode, but lacking the HTL portion of the double interlayer, improves the device performance, as evident by a PCE of 5.81%, J_{sc} of 16.7 mA/cm², V_{oc} of 0.59 V, and FF of 0.59. Greater improvement is achieved by including a double interlayer of MoO₃ with a HTL of MTDATA while having an inverted PV device structure, as indicated by the PCE of 6.24%, J_{sc} of 17.6 mA/cm², V_{oc} of 0.60 V, and FF of 0.59 for the device, where the comparative values for exemplary devices are easily seen in Table 1, below.

TABLE 1
Performance for PV Devices with
DTS-BTD: PC₇₀BM Active Layers

| | J_{sc} | V_{oc} | FF | PCE |
|---|---|---|---|---|
| Device Structure | (mA/cm²) | (V) | (%) | (%) |
| ITO/MoO₃//DTSBTD: | 12.78 | 0.61 | 61 | 4.91 |
| PC₇₀BM/LiF—Al | | | | |
| ITO/ZnO/DTSBTD: PC₇₀BM/MoO₃/Ag | 16.77 | 0.59 | 59 | 5.81 |
| ITO/ZnO/DTSBTD: | 17.61 | 0.60 | 59 | 6.24 |
| PC₇₀BM/MTDATA/MoO₃/Ag | | | | |

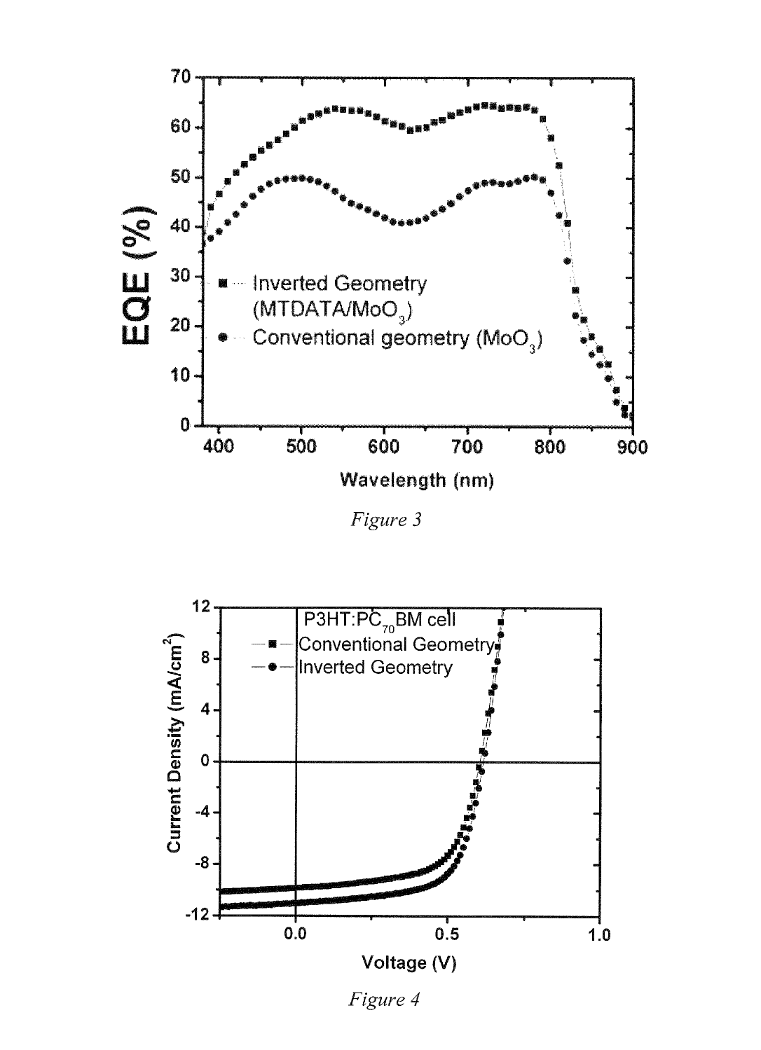

The enhancement in device performance for the inverted PV device with the double interlayer results from the efficient electron blocking by the HTL, MTDATA, and the enhanced charge extraction due to the MoO₃ layer. The shallow LUMO energy, 2.0 eV, of the MTDATA layer efficiently prevents migration of electrons from the active layer to the anode. External quantum efficiencies (EQEs) for PV devices with conventional and inverted geometries are shown in FIG. 3. The EQE of the inverted PV device with a double interlayer, MoO₃ and MTDATA, has a peak EQE of 64%, as opposed to a conventional PV device that has a peak EQE of only 48%.

Embodiments of the invention are not limited to those where the active material is DTS-BTD:PC₇₀BM. Rather, the efficiency of any organic PV cell employing a BHJ active layer can be improved by the use of an inverted geometry and including a double interlayer. This is illustrated by the inclusion of the double interlayer, MoO₃ with MTDATA, in an inverted PV cell that has a poly(3-hexylthiophene) P3HT:PC₇₀BM blend as a BHJ active layer. The J-V characteristics of an inverted PV device with a P3HT:PC70BM active layer and a MoO₃ with MTDATA double interlayer is demonstratively superior to a conventional design PV device that employs a MoO₃ interlayer between the transparent anode and active layer, as shown by their J-V Curves plotted in FIG. 4, and characterized by the values recorded in Table 2, below. As can be seen in Table 2, a significant improvement in efficiency is achieved by employing an inverted geometry with a double interlayer. The P3HT:PC₇₀BM based inverted PV cell with the double interlayer has a PCE of 4.62%, which is an improvement of 22% over that of a PV cell with a conventional geometry that lacks the double interlayer, which displays a PCE of only 3.80%.

TABLE 2
Performance for PV Devices with
DTS-BTD: PC₇₀BM Active Layers

| | J_{sc} | V_{oc} | FF | PCE |
|---|---|---|---|---|
| Device structure | (mA/cm²) | (V) | (%) | (%) |
| ITO/MoO₃//P3HT: | 9.84 | 0.60 | 65 | 3.80 |
| PC₇₀BM/LiF—Al | | | | |
| ITO/ZnO/P3HT: PC₇₀BM/MoO₃/Ag | 10.88 | 0.61 | 66 | 4.36 |
| ITO/ZnO/P3HT: | 11.33 | 0.62 | 66 | 4.62 |
| PC₇₀BM/MTDATA/MoO₃/Ag | | | | |

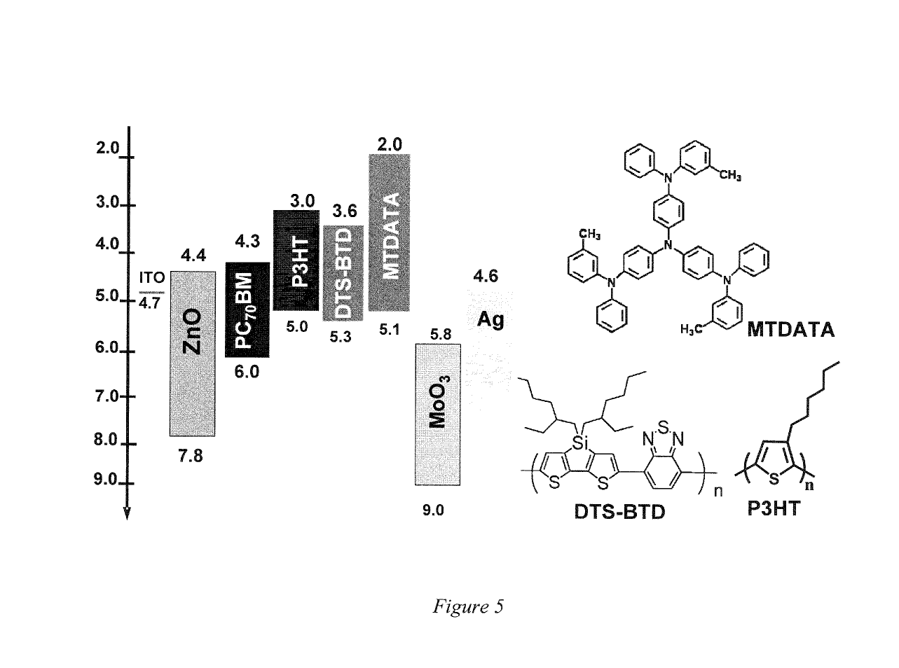

As can be appreciated by those skilled in the art in view of the teachings herein, many other anodes, cathodes, cathode interlayers, anode interlayers, and HTLs can be used by choosing materials with compatible LUMO and HOMO energies, such as those illustrated in FIG. 5. In other embodiments of the invention, other cathodes, anodes, anode double interlayers, cathode interlayers, and BHJ active layers can be used, in addition to those disclosed above. For example, the BHJ can comprise the electron-donating organic material: poly(3-hexylthiophene) (P3 HT); poly(2,7-(9-(2′-ethylhexyl)-9-hexyl-fluorene)-alt-5,5-(4′,7′-di-2-thienyl-2′,1′,3′-benzothiadiazole)) (PFDTBT); poly(2,6- (4,4-bis-(2-ethylhexyl)-4H-cyclopenta(2,1-b;3,4-b′)dithiophene)-alt-4,7-(2,1,3-benzothiadiazole)) (PCPDTBT); poly(p-phenylene-ethynylene)-alt-poly(p-phenylene-vinylene) (PPE-PPV); poly((2,7-(9-(2′-ethylhexyl)-9-hexyl-fluorene)-alt-5,5-(4′,7′-di-2-thienyl-2′, 1′, 3′-benzothiadiazole))-co-(2,7-(9-(2′-ethylhexyl)-9-hexyl-fluorene)-alt-2,5-thiophene)) (APFO-5); poly(4,8-bis-alkyloxybenzo(1,2-b:4,5-b′)dithiophene-2,6-diyl-alt-(alkylthieno(3,4-b)thiophene-2-(2-ethyl-1-hexanone)-2,6-diyl)) (PBDTTT-C); poly(4,8-bis-alkyloxybenzo(1,2-b:4,5-b′)dithiophene-2,6-diyl-alt-(thieno(3,4-b)thiophene-2-carboxylate)-2,6-diyl) (PBDTTT-E); poly(N-9′-heptadecanyl-2,7-carbazole-alt-5,5-(4′,7′-di-2-thienyl-2′, 1′, 3′-benzothiadiazole)) (PCDTBT); aluminum phthalocyanine chloride (AlPcCl); or copper phthalocyanine (CuPc); where the electron-donating organic material is combined with an electron-accepting material that can be, for example: a functional fullerene, such as PCBM, where the fullerene can be C₆₀ or C₇₀; ZnO nanoparticles; N-alkyl or N-aryl perylenediimides; perylenediimide containing polymers; CNPPV; TiO₂ nanoparticles: or Cd/Pb-based nanoparticles.

The anode for the inverted PV devices, according to embodiments of the invention, need not be silver, but can be, for example, calcium (Ca), aluminum (Al), magnesium (Mg), titanium (Ti), tungsten (W), gold (Au), other appropriate metals, or any alloys of these metals. In addition to ITO, according to embodiments of the invention, the transparent cathode can be: other conductive metal oxides such as fluorine-doped tin oxide and aluminum-doped zinc oxide; a metal oxide metal laminate, such as ITO/Ag/ITO; Al doped ZnO/metal; a thin metal layer, where the metal layer can be, for example, Ag, Au, Pd, Pt, Ti, V, Zn, Sn, Al, Co, Ni, Cu, or Cr; doped or undoped single walled carbon nanotubes (SWNTs); or patterned metal nanowires of gold, silver, or copper (Cu). In addition to ZnO, according to embodiments of the invention, the cathode interlayer can be, for example, LiF, LiCoO₂, CsF, Cs₂CO₃, TiO₂, or polyethylene oxide (PEO).

In addition to MoO₃, according to embodiments of the invention, the metal oxide of the anode double interlayer can be, for example, V₂O₅, WO₃, or NiO. In other embodiments of the invention, an alternative to the metal oxide can be any organic electron accepting transport material, for example, 1,4,5,8,9,12-hexaazatriphenylene-2,3,6,7,10,11-hexanitrile (HAT(CN)₆) or other n-type semiconductor organic material including, but not limited to: copper hexadecafluorophthalocyanine (F₁₆-CuPc); 2,3,5,6-tetrafluoro-7,7,8,8 -tetracyanoquinodimethane (F4TCNQ); 3,4,9,10-perylenetetra-carboxylic dianhydride (PTCDA); fluoro-substituted PTCDA; cyano-substituted PTCDA; naphthalene-tetracarboxylic-dianhydride (NTCDA); fluoro-substituted NTCDA; cyano-substituted NTCDA; and 3,4,9,10-perylene tetracarboxylic bisbenzimidazole (PTCBI).

In addition to MTDATA, according to embodiments of the invention, the electron accepting electron blocking material layer can be, for example: an aromatic amine having a plurality of nitrogen atoms, such as, 4,4′-bis[N-(p-tolyl)-N-phenyl-amino]biphenyl (TPD), 4,4′-bis[N-(1-naphthyl)-N-phenyl-amino]biphenyl (α-NPD), 4,4′-[bis-{(4-di-n-hexylamino) benzylideneamino}]stilbene (DHABS), or 4,4′-[bis-{(4-diphenylamino)benzylideneamino}]stilbene (DPABS); or a polymer, such as, poly-N,N′-bis(4-butylphenyl)-N,N′-bis(phenyl)benzidine (poly-TPD), poly(9,9-dioctylfluorene-co-N-[4-(3-methylpropyl)]-diphenylainine) (TFB), or a TFB analogue.

It should be understood that the examples and embodiments described herein are for illustrative purposes only and that various modifications or changes in light thereof will be suggested to persons skilled in the art and are to be included within the spirit and purview of this application.

We claim:

1. A polymer solar cell, comprising: a transparent cathode; an active layer; a double interlayer comprising a hole extracting layer and a hole transport/electron blocking layer; and an anode, wherein the double interlayer is situated between the active layer and the anode.

2. The polymer solar cell of claim 1, wherein the hole extracting layer comprises a metal oxide or an organic electron accepting transport material.

3. The polymer solar cell of claim 2, wherein the metal oxide comprises MoO₃, V₂O₅, NiO, or WO₃.

4. The polymer solar cell of claim 3, wherein the metal oxide comprises a plurality of nanoparticles.

5. The polymer solar cell of claim 2, wherein the organic electron accepting transport material comprises 1,4,5,8,9,12-hex aazatriphenylene-2,3,6,7,10,11-hexanitrile (HAT(CN)₆), copper hexadecafluorophthalocyanine (F₁₆-CuPc), 2,3,5,6-tetrafluoro-7,7,8,8-tetracyanoquinodimethane (F4TCNQ), 3,4,9,10-perylenetetra-carboxylic dianhydride (PTCDA), fluoro-substituted PTCDA, cyano-substituted PTCDA, naphthalene-tetracarboxylic-dianhydride (NTCDA), fluoro-substituted NTCDA, cyano-substituted NTCDA, or 3,4,9,10-perylene tetracarboxylic bisbenzimidazole (PTCBI).

6. The polymer solar cell of claim 1, wherein the hole transport/electron blocking layer comprises: 4,4,4″tris[N-(3 -methylphenyl)-N-phenyl amino]triphenyl amine (MTDATA); poly(9,9-dioctylfluorene-co-N-[4-(3-methylpropyl)]diphenylamine) (TFB); poly(N,N′-bis(4-butylphenyl)-N,N′-bis(phenyl)benzidine) (poly-TPD); 4,4′-bis[N-(p-tolyl)-N-phenyl-amino]biphenyl (TPD); 4,4′-bis[N-(1-naphthyl)-N-phenyl-amino]biphenyl (α-NPD); 4,4′-[bis-{(4-di-n-hexylamino)benzylideneamino}]stilbene (DRABS); 4,4′-[bis-{(4-diphenylamino) benzylideneamino}]stilbene (DPABS); or a TFB analogue.

7. The polymer solar cell of claim 1, wherein the transparent cathode comprises: indium-tin-oxide (ITO); ITO/Ag/ITO; Al doped ZnO/metal; a thin metal layer; doped or undoped single walled carbon nanotubes (SWNTs); or patterned metal nanowires comprising gold, silver, or copper.

8. The polymer solar cell of claim 7, wherein the thin metal layer comprises Ag, Au, Pd, Pt, Ti, V, Zn, Sn, Al, Co, Ni, Cu, or Cr.

9. The polymer solar cell of claim 1, wherein the anode comprises a metal or a metal alloy.

10. The polymer solar cell of claim 9, wherein the metal comprises silver (Ag), calcium (Ca), aluminum (Al), magnesium (Mg), titanium (Ti), tungsten (W), or gold (Au).

11. The polymer solar cell of claim 1, further comprising a cathode interlayer situated between the active layer and the transparent cathode.

12. The polymer solar cell of claim 11, wherein the cathode interlayer comprises ZnO, LiF, LiCoO₂, CsF, Cs₂CO₃, TiO₂, or a polar or ionic polymer.

13. The polymer solar cell of claim 12, wherein the polar or ionic polymer comprises polyethylene oxide (PEO).

14. The polymer solar cell of claim 1, wherein the active layer comprises a bulk heterojunction (BHJ) active layer comprising an electron-donating material and an electron-accepting material.

15. The polymer solar cell of claim 14, wherein the electron-donating material comprises poly [(4,4′-bis(2-ethylhexyl)dithienol [3,2-b:2′,3′-d]silole)-2,6-diyl-alt-(2,1,3-benzothiadiazole)-4, 7-diyl] (DTSBTD): poly(3-hexylthiophene) (P3HT); poly(2,7-(9-(2′-ethylhexyl)-9-hexyl-fluorene)-alt-5,5-(4′, 7′-di-2-thienyl-2′, 1′,3′-benzothiadiazole)) (PFDTBT); poly(2,6-(4,4-bis-(2-ethylhexyl)-4H-cyclopenta(2,1-b;3,4-6′)dithiophene)-alt-4,7-(2,1,3-benzothiadiazole)) (PCPDTBT); poly(p-phenylene-ethynylene)-alt-poly(p-phenylene-vinylene) (PPE-PPV); poly((2,7-(9-(2′-ethylhexyl)-9-hexyl-fluorene)-alt-5,5-(4′,7′-di-2-thienyl-2′, 1′,3′-benzothiadiazole))-co-(2,7-(9-(2′-ethylhexyl)-9-hexyl-fluorene)-alt-2,5-thiophene)) (APFO-5); poly(4,8-bis-alkyloxybenzo(1,2-b :4,5-b′)dithiophene-2,6-diyl-alt-(alkylthieno(3,4-b)thiophene-2-(2-ethyl-1-hexanone)-2,6-diyl) (PBDTTT-C); poly(4,8-bis-alkyloxybenzo(1,2-b:4,5-b′)dithiophene-2,6-diyl-alt-(thieno(3,4-b)thiophene-2-carboxylate)-2,6-diyl) (PBDTTT-E); poly [N-9′-heptadecanyl-2,7-carbazole-alt-5,5-(4′,7′-di-2-thienyl-2′,1′,3′-benzothiadiazole)] (PCDTBT); aluminum phthalocyanine chloride (AlPcCl); or copper phthalocyanine (CuPc).

16. The polymer solar cell of claim 14, wherein the electron-accepting material comprises: {6,6}-phenyl-C₇₁ butyric acid methyl ester (PC₇₀BM); {6,6}-phenyl-C₆₁ butyric acid methyl ester (PC₆₀BM); ZnO nanoparticles; N-alkyl or N-aryl perylenediimides; perylenediimide containing polymers; CNPPV; TiO₂ nanoparticles; or Cd/Pb-based nanoparticles.
